(19) United States
(12) Patent Application Publication
(10) Pub. No.: US 2017/0125127 A1
(43) Pub. Date: May 4, 2017

(54) MEMORY SYSTEM AND OPERATING METHOD THEREOF

(71) Applicant: SK hynix Inc., Gyeonggi-do (KR)

(72) Inventor: Min Chul KIM, Seoul (KR)

(21) Appl. No.: 15/075,296

(22) Filed: Mar. 21, 2016

(30) Foreign Application Priority Data
Nov. 3, 2015 (KR) 10-2015-0154016

(51) Int. Cl. G11C 29/42; G06F 11/10; G11C 29/52; G11C 29/44

(52) U.S. Cl. CPC G11C 29/42; G11C 29/44; G06F 11/1068; G11C 29/52

(57) ABSTRACT

A memory system may include a semiconductor memory device including a plurality of memory blocks, and a controller for controlling the semiconductor memory device to perform a general operation on a selected memory block among the plurality of memory blocks. When the selected memory block is determined as fail based on a result of a status check operation performed during the general operation, the controller performs a verify operation of determining whether the selected memory block is a fake bad block or a real bad block.

### CROSS-REFERENCE TO RELATED APPLICATION

The present application claims priority to Korean patent application number 10-2015-0154016, filed on Nov. 3, 2015, the entire disclosure of which is herein incorporated by reference in its entirety.

### BACKGROUND

1. Field

An aspect of the present disclosure relates generally to an electronic device, and more particularly, to a memory system and an operating method thereof.

2. Description of the Related Art

Use of large-capacity files, such as music files and moving image files in, portable electronic devices has been made possible with the advent of large storage capacity memory systems based on semiconductor technology. Memory systems including a plurality of memory devices for increasing their storage capacity have also been developed. Memory systems including a plurality of memory devices generally require high operational speeds for satisfactory performance.

The plurality of memory devices included in the memory system may be implemented using semiconductor materials such as silicon (Si), germanium (Ge), gallium arsenide (GaAs), or indium phosphide (InP). Semiconductor memory devices are generally classified into volatile and nonvolatile memory devices.

Unlike nonvolatile memory devices, volatile memory devices lose stored data when the device is powered off. Examples of volatile memory devices include a static random access memory (SRAM), a dynamic RAM (DRAM), a synchronous DRAM (SDRAM), and the like. Examples of nonvolatile memory devices include a read only memory (ROM), a programmable ROM (PROM), an erasable programmable ROM (EPROM), an electrically erasable programmable ROM (EEPROM), a flash memory, a phase-change RAM (PRAM), a magnetoresistive RAM (MRAM), a resistive RAM (RRAM), a ferroelectric RAM (FRAM), and the like. Flash memory devices have gained widespread acceptance and may generally classified into NOR or NAND type flash memory.

Continuous consumer appetite for faster and larger capacity portable devices requires continuous improvements in the operational efficiency of memory systems.

### SUMMARY

Various aspects of the present disclosure provide a memory system and an operating method thereof, which more accurately determine whether a memory block included in the memory system is a fake bad block or a real bad block, thereby improving the overall efficiency of the memory system.

According to an aspect of the present disclosure, there is provided a memory system including: a semiconductor memory device including a plurality of memory blocks; and a controller suitable for controlling the semiconductor memory device to perform a first operation on a memory block selected among the plurality of memory blocks, the first operation including performing a status check for determining whether the selected memory block is a fail or a pass; wherein if the selected memory block is determined as a fail the controller performs a second operation for determining whether the selected memory block is a fake bad block or a real bad block.

According to an aspect of the present disclosure, there is provided a method of operating a memory system, the method including: performing a first operation of a selected memory block among a plurality of memory blocks said first operation including performing a status check operation on the selected memory block; performing a second operation of determining whether the selected memory block is a real bad block or a fake bad block, when the selected memory block is determined as fail based on a result of the status check operation; and continuously performing the first operation on the selected memory block, when the selected memory block is determined as the fake bad block based on a result of the second operation.

According to an aspect of the present disclosure, there is provided a method of operating a memory system, the method including: performing a program or erase operation of a selected memory block among a plurality of memory blocks; performing a status check operation on the selected memory block; and performing a first verify operation of determining whether the selected memory block is determined as a fake bad block more than a set number of times when the selected memory block is determined as fail based on a result of the status check operation.

### BRIEF DESCRIPTION OF THE DRAWINGS

Various embodiments of the present disclosure will be described in details with reference to the attached drawings in which:

FIG. 1 is a block diagram illustrating a memory system, comprising a memory device coupled to a controller, according to an embodiment of the present disclosure.

FIG. 2 is a block diagram illustrating in more detail an example of the semiconductor memory device, according to an embodiment of the present disclosure.

FIG. 3 is a flowchart illustrating an operating method of a memory system, according to an embodiment of the present disclosure.

FIG. 4 is a flowchart illustrating an operating method of the memory system, according to another embodiment of the present disclosure.

FIG. 5 is a block diagram illustrating a memory system, according to another embodiment of the present disclosure.

FIG. 6 is a block diagram illustrating an application example of the memory system of FIG. 5, according to an embodiment of the present disclosure.

FIG. 7 is a block diagram illustrating a computing system including the memory system of FIG. 6, according to an embodiment of the present disclosure.

### DETAILED DESCRIPTION

In the following detailed description only certain exemplary embodiments of the present disclosure have been shown and described, simply by way of illustration. As those skilled in the art would realize, the described embodiments may be modified in various different ways, all without departing from the spirit or scope of the present disclosure. Accordingly, the drawings and description are to be regarded as illustrative in nature and not restrictive.

In the drawings, dimensions may be exaggerated for clarity of illustration. It will be understood that when an element is referred to as being “between” two elements, it can be the only element between the two elements, or one or more intervening elements may also be present. Like reference numerals refer to like elements throughout.

It will be further understood that, although the terms “first”, “second” “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element component, region, layer or section described below could be termed a second element, component, region, layer or section, without departing from the spirit and scope of the present disclosure.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises”, “comprising”, “may include”, “including” “has” or “having” when used in this specification, specify the presence of the stated features, integers, operations, elements, and/or components, but do not preclude the presence or addition of one or more other non-stated features, integers, operations, elements, components, and/or groups thereof. As used herein, the term “and/or” may include any and all combinations of one or more of the associated listed items.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the following description, numerous specific details are set forth in order to provide a thorough understanding of the present disclosure. The present disclosure may be practiced without some or all of these specific details. In other instances, well-known process structures and/or processes have not been described in detail in order not to unnecessarily obscure the present disclosure.

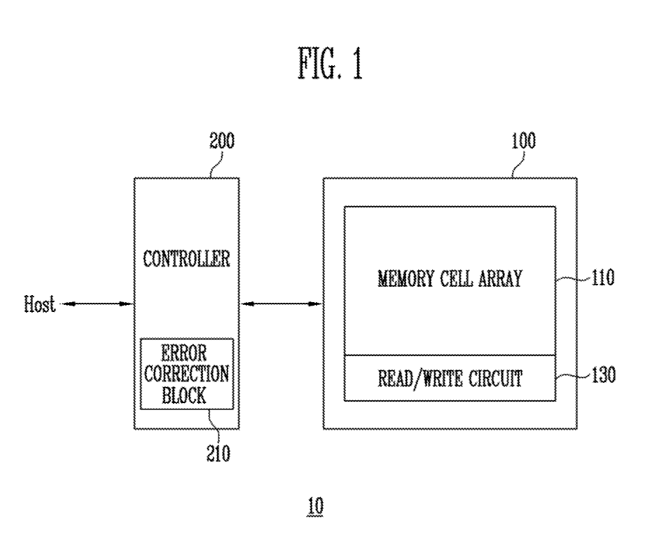

FIG. 1 is a block diagram illustrating a memory system 10 including a semiconductor memory device 100.

Referring to FIG. 1, the memory system 10 may include the semiconductor memory device 100 and a controller 200. The semiconductor memory device 100 may include a memory cell array 110 and a read/write circuit 130 connected to the memory cell array 110.

The memory cell array 110 may include a plurality of memory blocks, and each of the plurality of memory blocks may include a plurality of memory cells. Each of the plurality of memory cells may be defined as a multi level memory cell that may store 2 or more bits of data Detailed configuration and operation of the memory cell array 110 will be described later.

The semiconductor memory device 100 may operate under control of the controller 200. If command for a general operation (e.g., an erase or program operation) may be received from the controller 200, the semiconductor memory device 100 performs the erase or program operation on memory cells (selected memory cells) of a memory block indicated by an address received together with the command. In this case, the semiconductor memory device 100 may alternately perform a plurality of erase voltage applying operations and a plurality of verify operations in the erase operation, and perform the erase voltage applying operation by using an incremental step pulse erase (ISPE) method. Also, the semiconductor memory device 100 may alternately perform a plurality of program voltage applying operations and a plurality of verify operations in the program operation, and perform the program voltage applying operation by using an incremental step pulse program (ISPP) method. When the above-described erase and program operations are determined as fail based on a result of the verify operation, even though the erase voltage applying operations and the program voltage applying operations are performed a set number of erase voltage applying times and program voltage applying times, a corresponding memory block may be determined as a bad block according to a status check operation thereof.

However, although the erase and program operations are determined as fail in the above-described status check operation of the memory block, the memory block may properly may operate in practice. For example, although the erase or program operation may be determined as fail in the status check operation thereof, the distribution of threshold voltages of memory cells included in a real memory block may be within a normal range, and the number of error checking and correction or error correction code (ECC) fail bits may be detected smaller than the number of ECC maximum correctable bits. Therefore, although the status check operation of a normal memory block may be properly performed, the memory block may be determined as a bad block due to some errors of firmware or an unknown error of the memory system, thereby reducing the efficiency of the memory system.

Accordingly, the controller 200 performs a verify operation on a memory block determined as fail in its status check operation, thereby dividing the corresponding memory block into a fake bad block or a real bad block. In this case, when the memory block determined as fail based on the result of the status check operation may be determined as a fake bad block based on a result of the verify operation of the controller 200, the memory block may be used as a normal memory block, so that the efficiency of the memory system may be improved. This will be described later.

In an embodiment, the semiconductor memory device 100 may be a flash memory device. However, it will be understood that the present disclosure may be not limited to the flash memory device.

The controller 200 may be connected between the semiconductor memory device 100 and a host Host. The controller 200 may be configured to interface between the host Host and the semiconductor memory device 100. For example, in an erase or program operation according to a request from the host Host, the controller 200 may convert into a physical block address, a logical block address received from the host Host, and provide the semiconductor memory device 100 with the converted physical block address together with a corresponding command. Also, in the erase or program operation, the controller 200 may receive information of the semiconductor memory device 100, stored in a system memory block among the plurality of the memory blocks in the semiconductor memory device 100, to control the erase or program operation.

In an embodiment the controller 200 may include an error correction block 210. The error correction block 210 may be configured to detect and correct errors included in data received from the semiconductor memory device 100. An error correction function performed by the error correction block 210 may be limited depending on a number of fail bits of the data received from the semiconductor memory device 100. When the number of fail bits of the data received from the semiconductor memory device 100 may be smaller than a specific value, the error correction block 210 performs an error detection and correction function. When the number of fail bits of the data received from the semiconductor memory device 100 may be greater than a specific value, the error detection and correction function cannot be performed.

When a selected memory block among the plurality of memory blocks included in the semiconductor memory block 100 may be determined as fail based on the result of the status check operation during the erase or program operation, the controller 200 may control the semiconductor memory device 100 to determine whether the selected memory block may be a fake bad block or a real bad block. To this end, the controller 200 may read the history information of fake bad blocks stored in the system memory block of the semiconductor memory block 100, and checks whether the selected memory block has a history of being determined as a fake bad block in the read history information. Also, the controller 200 determines whether error correction may be possible by performing an error detection operation on the selected memory block by using the error correction block 210. Also, the controller 200 controls the semiconductor memory device 100 so that the status check operation may be re-performed by initializing a command for a general operation being performed and re-performing the operation being performed. The controller 20 determines whether the selected memory block may be the fake bad block or the real bad block, based on the above-described operations. An operating method of this will be described in detail later.

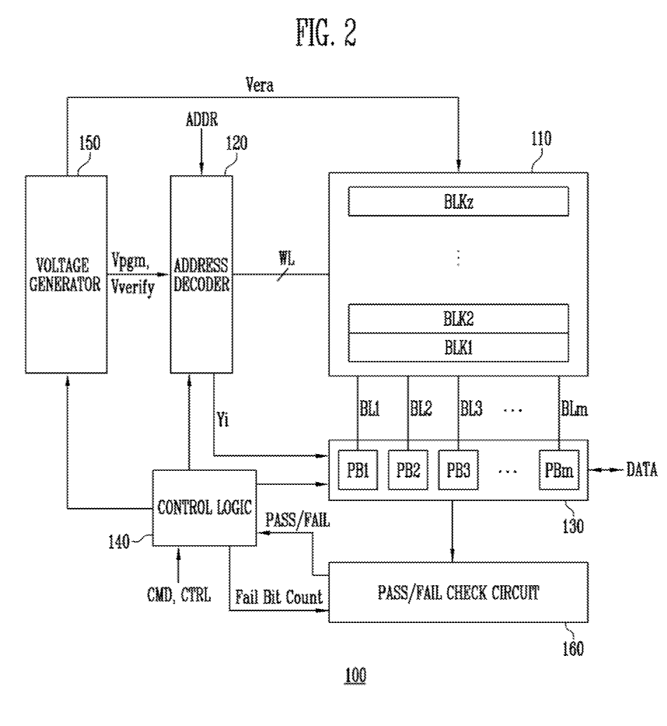

FIG. 2 is a block diagram illustrating the semiconductor memory device shown in FIG. 1.

Referring to FIG. 2, the semiconductor memory device 100 may include a memory cell array 110, an address decoder 120, a read/write circuit 130, a control logic 140, a voltage generator 150, a pass/fail check circuit 160.

The memory cell array 110 may include a plurality of memory blocks BLK1 to BLKz. The plurality of memory blocks BLK1 to BLKz may be connected to the address decoder 120 through word lines WL. The plurality of memory blocks BLK1 to BLKz may be connected to the read/write circuit 130 through bit lines BL1 to BLm. Each of the plurality of memory blocks BLK1 to BLKz may include a plurality of memory cells. In an embodiment, the plurality of memory cells may be nonvolatile memory cells. A plurality of memory cells connected to the same word line are defined as one page. That is, the memory cell array 110 may include a plurality of pages.

Some memory blocks among the plurality of memory blocks BLK1 to BLKz may be defined as a system memory block. The system memory block may store important data of the semiconductor memory device 100. For example, the system memory block may store bad block information, fake bad block history information, and the like for the memory blocks BLK1 to BLKz. The fake bad block history information may include information on a history, a number of times and other parameters that may be used to determine whether or not each block may be a fake bad block. The bad block history information may include information on a history, a number of times, and other parameters that may be used to determine whether or not each block may be a bad block. The bad block information and the fake bad block history information may be updated by checking a status of the semiconductor memory device 100 according to an operation of the memory system 10. The bad block information and the fake bad block history information may be updated continuously in real time every time the status of the semiconductor device 100 is checked.

The address decoder 120, the read/write circuit 130, and the voltage generator 150 may operate as peripheral circuits for driving the memory cell array 110.

The address decoder 120 may be connected to the memory cell array 110 through the word lines WL. The address decoder 120 may be configured to may operate under control of the control logic 140. The address decoder 120 receives an address ADDR through an input/output buffer (not shown) in the semiconductor memory device 100.

The address decoder 120 applies a program pulse Vpgm generated by the voltage generator 150 to a selected word line among word lines of a selected memory block in a program pulse applying operation, and applies a verify voltage Vverify generated by the voltage generator 150 to the selected word line among the word lines of the selected memory block in a verify operation, during a program operation.

A program operation of the semiconductor memory device 100 may be performed on a basis of pages, and an erase operation of the semiconductor memory device 100 may be performed on a basis of blocks or pages. The address ADDR received when the program operation may be requested may include a block address, a row address, and a column address. The address decoder 120 selects one memory block and one word line based on the block address and the row address. The column address may be decoded by the address decoder 120 to be provided to the read/write circuit 130.

The read/write circuit 130 may include a plurality of page buffers PB1 to PBm. The plurality of page buffers PB1 to PBm may be connected to the memory cell array 110 through the bit lines BL1 to BLm. Each of the plurality of page buffers PB1 to PBm temporarily may store data DATA inputted from the outside in a program operation, and controls the potential level of a corresponding bit line to be a program permission voltage or a program prohibition voltage based on the stored data. In a program verify operation or an erase verify operation, the read/write circuit 130 senses potential levels or current amounts of corresponding bit lines BL1 to BLm, and performs a verify operation by using the sensed potential levels or current amounts.

The read/write circuit 130 may operate under control of the control logic 140. As an exemplary embodiment, the read/write circuit 130 may include page buffers (or page registers), a column select circuit, and the like.

The control logic 140 may be connected to the address decoder 120, the read/write circuit 130, and the voltage generator 150. The control logic 140 receives a command CMD through the input/output buffer (not shown) in the semiconductor memory device 100. The control logic 140 may be configured to control overall operations of the semiconductor memory device 100 in response to the command CMD. The control logic 140 controls the voltage generator 150 and the address decoder 120 so that a program pulse Vpgm or a verify voltage Vverify may be applied to a selected memory block in program and verify operations. Also, the control logic 140 controls the voltage generator 150 and the address decoder 120 so that an erase voltage Vera or a verify voltage Vverify may be applied to a selected memory block in erase and verify operations. The control logic 140 controls the read/write circuit 130 to perform a verify operation by sensing potentials of the bits lines BL1 to BLm in the memory cell array 110. The control logic 140 controls the pass/fail check circuit 160 by outputting a fail bit count signal Fail Bit Count in a status check operation of a selected memory block.

In the embodiment of the present disclosure, it is illustrated that the error correction block 210 may be included in the controller 200 as shown in FIG. 1, but the semiconductor memory device 100 may be configured so that the error correction block 210 may be included in the control logic 140.

The voltage generator 150 may generate a program pulse Vpgm to be applied to a selected memory block in a program pulse applying operation, and may generate an erase voltage Vera to be applied to a selected memory block in an erase operation. Also, the voltage generator 150 may generate a verify voltage Vverify to be applied to a selected memory block in a verify operation. Any suitable voltage generator circuit may be used.

The pass/fail check circuit 160 may output a pass signal PASS/FAIL by counting the number of fail bits of memory cells in which program errors or erase errors occur in a selected page of a selected memory block in response to a fail bit count signal Fail Bit Count when a status check operation is performed. When the counted number of fail bits is greater than the number of ECC maximum correctable bits, may be corrected by using the error correction block 210, the pass/fail check circuit 160 may output a fail signal FAIL. When the counted number of fail bits is equal to or smaller than the number of ECC maximum correctable bits the pass/fail check circuit 160 may output a pass signal PASS. The number of ECC maximum correctable bits may be set based on a request of the host Host. For example, the number of ECC maximum correctable bits may be 18.

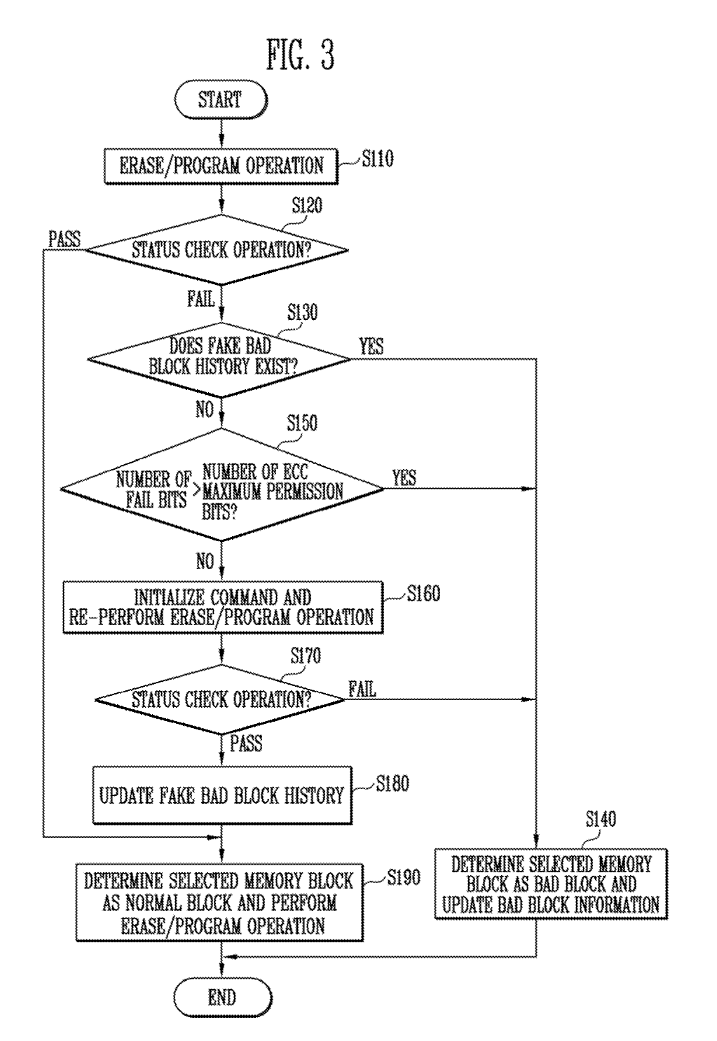

FIG. 3 is a flowchart illustrating an operating method of the memory system, according to an embodiment of the present disclosure.

The operating method of the memory system 10 according to the embodiment of the present disclosure will be described with reference to FIGS. 1 to 3.

1) Erase/Program Operation (S110)

If an erase or program operation request is received from the host Host, the controller 200 may convert a logical block address received from the host Host to a physical block address, and provides the semiconductor memory device 100 with the converted physical block address together with a corresponding command.

The control logic 140 of the semiconductor memory device 100 controls, the address decoder 120 the read/write circuit 130, and the voltage generator 150 to perform an erase or program operation in response to a command CMD received from the controller 200.

The address decoder 120, the read/write circuit 130, and the voltage generator 150 perform an erase or program operation on a selected memory block among the plurality of memory blocks BLK1 to BLKm included in the memory cell array 110 under control of the control logic 140.

2) Status Check Operation (S120)

A status check operation may be performed in the erase or program operation on the selected memory block. The status check operation may be preferably performed when the selected memory block may be determined as fail based on an erase verify result even after an erase voltage Vera may be applied a set number of times in the erase operation or when the selected memory block may be determined as fail based on a program verify result even after a program pulse Vpgm may be applied a set number of times in the program operation.

In the status check operation, the pass/fail check circuit 160 may output a pass or fail signal PASS/FAIL by counting a number of fail bits of memory cells in which program errors or erase errors occur in a selected page of the selected memory block in response to a fail bit count signal Fail Bit Count. When the counted number of fail bits is greater than the number of ECC maximum correctable bits, which may be corrected by using the error correction block 210, the pass/fail check circuit 160 may output a fail signal FAIL. When the counted number of fail bits is equal to or smaller than the number of ECC maximum correctable bits, the pass/fail check circuit 160 may output a pass signal PASS. In this case, the number of ECC maximum correctable bits may be set based on a request of the host Host.

The control logic 140 may notify, to the controller 200, a pass/fail status of the erase or program operation of the selected memory block in response to the pass/fail signal PASS/FAIL received from the pass/fail check circuit 160.

3) Identification of Fake Bad Block History (S130)

When a determination result is received from the control logic 140 that the selected memory block is in a fail state, as a result of the erase or program operation, the controller 200 may identify whether the selected memory block has a history of being determined as a fake or bad block. More specifically, the controller 200 may read fake or bad block history information stored in a system memory block (e.g., BLKz) among the plurality of memory blocks BLK1 to BLKz included in the semiconductor memory device 100, and may identify whether the history of the selected memory block exists in the read fake or bad block history information.

When the history of the selected memory block exists in the read fake or bad block history information, the controller 200 may determine the selected memory block as a bad block.

4) Update of Bad Block Information (S140)

When the selected memory block is determined to be a bad block, the controller 200 may update bad block information by storing, in the system memory block (e.g., BLKz), information that the selected memory block may be the bad block.

5) Identification of Number of Fail Bits (S150)

When the selected memory block has no history of a fake or bad block, based on a result of the identification of the fake or bad block history (S130), the controller 200 may identify the number of fail bits of the selected memory block.

For example, the pass/fail check circuit 160 may count the number of fail bits of memory cells in which program errors or erase errors occur in a selected page of the selected memory block in response to a fail bit count signal Fail Bit Count, and may compare the counted number of fail bits with the number of ECC maximum correctable bits, correctable by using the error correction block 210. The pass/fail check circuit 160 may determine whether or not the counted number of fail bits is greater than the number of ECC maximum correctable bits. The above-described operation may be performed by the pass/fail check circuit 160 in the status check operation (S120). Preferably, the above-described operation may be repeated so as to improve the accuracy thereof.

As a result of the identification of the number of fail bits (S150), when it is determined that the counted number of fail bits of the selected memory block is greater than the number of FCC maximum correctable bits, the controller 200 may determine the selected memory block as a bad block.

6) Re-Performance of Erase/Program Operation (S160)

As a result of the identification of the number of fail bits (S150), when it is determined that the counted number of fail bits of the selected memory block is equal to or smaller than the number of FCC maximum correctable bits, the controller 200 initializes the command for the erase or program operation.

The control logic 140 repeats the erase or program operation of the selected memory block in response to the initialized command.

7) Status Check Operation (S170)

A status check operation may be performed during the erase or program operation on the selected memory block. The status check operation may be performed in the same manner as the above-described status check operation (S120).

The control logic 140 may notify, to the controller 200, a pass/fail status of the erase or program operation of the selected memory block in response to the pass/fail signal PASS/FAIL outputted from the pass/fail check circuit 160.

When the selected memory block is determined as fail based on a result of the status check operation (S170), the controller 200 may determine the selected memory block as a bad block.

8) Update of Fake Bad Block History (S180)

When the selected memory block is determined as pass based on a result of the above-described status check operation (S170), the controller 200 does not determine the selected memory block as a real or bad block but may determine the selected memory block as a fake or bad block.

The controller 200 may update fake and/or bad block history information by storing, in the system memory block (e.g., BLKz), a history where the selected memory block is determined as a fake or bad block.

9) Re-Performance of Erase/Program Operation

After the above-described update of the fake and bad block history (S180), the controller 200 may determines that the selected memory block may not be a real bad block.

Thus, the controller 200 may output, to the control logic 140, the command for the erase or program operation on the selected memory block.

The control logic 140 may determine the selected memory block to be a normal memory block, and continuously perform the erase or program operation.

As described above, in an operating method of the memory system according to an embodiment of the present disclosure, when a selected memory block is determined as fail based on a result of the status check operation during an erase or program operation, the controller 200 may determine whether the selected memory block may be a real bad block or a fake bad block by performing a verify operation including the identification of the fake bad block history (S130), the identification of the number of fail bits (S150), and the status check operation (S170) after the re-performance of the erase/program operation (S160). Thus, when the selected memory block is determined to be a fake bad block, the selected memory block may be used as a normal memory block, thereby improving the efficiency of the memory system.

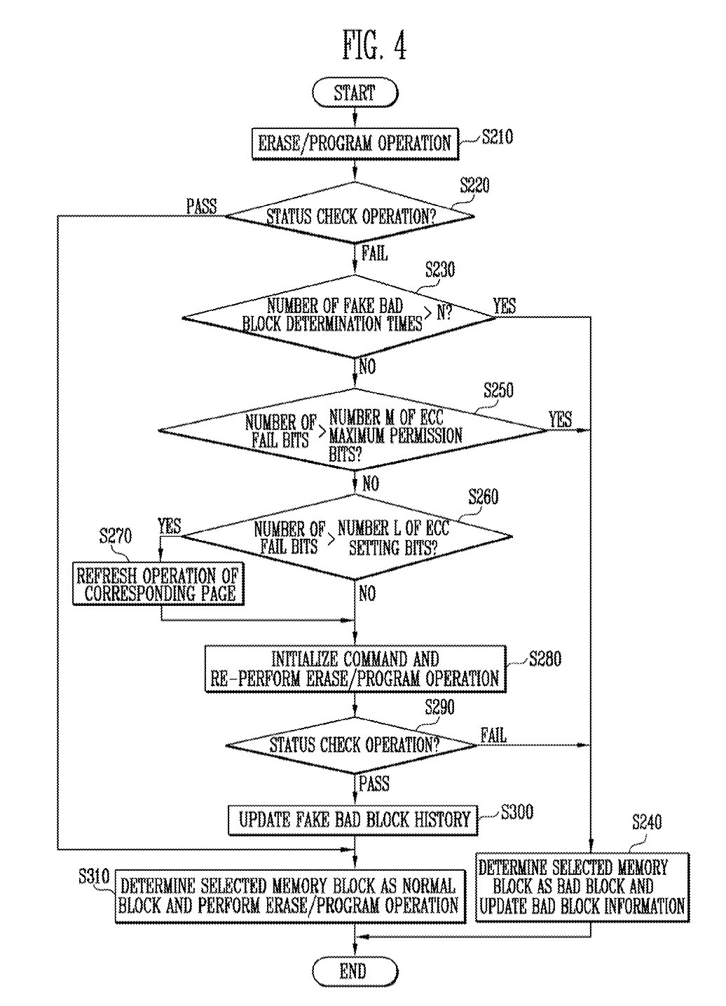

FIG. 4 is a flowchart illustrating an operating method of the memory system, according to another embodiment of the present disclosure.

The operating method of the memory system 10 will be described with reference to FIGS. 1, 2, and 4.

1) Erase/Program Operation (S210)

If an era se or program operation request is received from the host Host, the controller 200 may convert a logical block address received from the host Host to a physical block address, and provide the semiconductor memory device 100 with the converted physical block address together with a corresponding command.

The control logic 140 of the semiconductor memory device 100 may control the address decoder 120, the read/write circuit 130, and the voltage generator 150 to perform an erase or program operation in response to a command CMD received from the controller 200.

The address decoder 120, the read/write circuit 130, and the voltage generator 150 may perform an erase or program operation on a selected memory block among the plurality of memory blocks BLK1 to BLKm included in the memory cell array 110 under control of the control logic 140.

2) Status Check Operation (S220)

A status check operation may be performed in the erase or program operation on the selected memory block. Preferably, the status check operation may be performed when the selected memory block is determined as fail based on an erase verify result even after an erase voltage Vera is applied a set number of times in the erase operation. Also, preferably, the status check operation may be preferably performed when the selected memory block is determined as fail based on a program verify result even after a program pulse Vpgm is applied a set number of times in the program operation.

In the status check operation, the pass/fail check circuit 160 may output a pass or a fail signal PASS/FAIL by counting the number of fail bits of memory cells in which program errors or erase errors occur in a selected page of the selected memory block in response to a fail bit count signal Fail Bit Count. When the counted number of fail bits is greater than the number of ECC maximum correctable bits, the pass/fail check circuit 160 may output a fail signal FAIL. When the counted number of fail bits is equal to or smaller than the number of ECC maximum correctable bits, the pass/fail check circuit 160 may output a pass signal PASS. The number of ECC maximum correctable bits may be set based on a request of the host Host.

The control logic 140 may notify to the controller 200 a pass/fail status of the erase or program operation of the selected memory block in response to the pass/fail signal PASS/FAIL outputted from the pass/fail check circuit 160.

3) Identification of Number of Fake Bad Block Determination Times (S230)

When, as a result of an erase or a program operation, a determination result is received from the control logic 140 that the selected memory block is in a fail state, the controller 200 may identify whether the selected memory block has a history of being determined as a fake or bad block. More specifically, the controller 200 may read fake or bad block history information stored in a system memory block (e.g., BLKz) among the plurality of memory blocks BLK1 to BLKz included in the semiconductor memory device 100 and identify whether the selected memory block has a history in the read fake or bad block history information.

When the selected memory block has a history in the read fake or bad block history information the controller 200 may determine whether the selected memory block has been determined as a fake or bad block more than a preset number N of times.

When the selected memory block has a history of a fake or bad block and has been determined as a fake car bad block more than the preset number N of times, the controller 200 may determine the selected memory block as a bad block.

4) Update of Bad Block Information (S240)

When the selected memory block is determined as a bad block, the controller 200 updates bad block information by storing, in the system memory block (e.g., BLKz), information denoting the selected memory block as a bad block.

5) Comparison of Number of Fail Bits with Number of ECC Maximum Correctable Bits (S250)

When the selected memory block has no history of a fake or bad block, based on a result of the identification of the number of fake or bad block determination times (S230), the controller 200 may count the number of fail bits of the selected memory block and compare the counted number of fail bits with the number M of ECC maximum correctable bits.

For example, the pass/fail check circuit 160 may count the number of fail bits of memory cells in which program errors or erase errors occur in a selected page of the selected memory block in response to a fail bit count signal Fail Bit Count, and may determine whether or not the counted number of fail bits are greater than the number M of ECC maximum correctable bits that may be corrected by using the error correction block 210. The above-described operation may be performed by the pass/fail check circuit 160 in the status check operation (S220). Preferably, the above-described operation may be repeated (re-performed) to further improve the accuracy thereof.

As a result of the comparison of the number of fail bits with the number of ECC maximum correctable bits (S250), when it is determined that the counted number of fail bits of the selected memory block is greater than the number M of ECC maximum correctable bits, the controller 200 may determine that the selected memory block is a bad block.

6) Comparison of Number of Fail Bits with Number of ECC Setting Bits (S260)

When the counted number of fail bit is equal to or smaller than the number M of ECC maximum correctable bits as a result of the comparison of the number of fail bits with the number of ECC maximum correctable bits (S250), the controller 200 may compare the counted number of fail bits with the number L of ECC setting bits. The number L of ECC setting bits may be preferably smaller than the number M of ECC maximum correctable bits.

When it is determined that the counted number of fail bits is greater than the number L of ECC setting bits, the fail bits in the selected page of the selected memory block may be corrected by the error correction block 210. However, it may be estimated that the number of fail bits is greater than the number L of ECC setting bits and approaches the number M of ECC maximum correctable bits.

7) Refresh Operation of Corresponding Page (S270)

As a result of the comparison of the number of fail bits with the number of ECC setting bits (S260), when it is determined that the counted number of fail bits is greater than the number L of ECC setting bits the controller 200 programs data stored in the corresponding page of the selected memory block to another page of the same memory block or another memory block.

When it is determined that the counted number of fail bits is greater than the number L of ECC setting bits L, the fail bits in the selected page of the selected memory block may be corrected by the error correction block 210. However, it may be estimated that the number of fail bits is greater than the number L of ECC setting bits and approaches the number M of ECC maximum correctable bits. In this case, it is likely that the number of fail bits will be increased and the fail bits will be uncorrectable in data of the selected page of the selected memory block.

Thus, the controller 200 may read data in the selected page and allow fail bits of the data to be corrected by the error correction block 210. Then, the controller 200 programs the corrected data to another page of the same memory block or another memory block, thereby performing a refresh operation.

8) Re-Performance of Erase/Program Operation (S280)

As a result of the comparison of the number of fail bits with the number of ECC setting bits (S260), when the counted number of fail bits of the selected memory block is equal to or smaller than the number L of ECC setting bits, the controller 200 initializes the command for the erase or program operation.

The control logic 140 may repeat (re-performs) the eras e or program operation of the selected memory block in response to the initialized command.

Also the control logic 140 may repeat (re-performs) the erase or program operation of the selected memory block after the refresh operation of a corresponding page of step 270.

9) Status Check Operation (S290)

Following step S280, a status check operation may be performed during the erase or program operation on the selected memory block. The status check operation may be performed in the same manner as the above-described status check operation (S220).

The control logic 140 may notify, to the controller 200, a pass/fail status of the erase or program operation of the selected memory block in response to the pass/fail signal PASS/FAIL outputted from the pass/fail check circuit 160.

When the selected memory block is determined as fail based on a result of the status check operation (S290), the controller 200 may determine the selected memory block as a bad block.

10) Update of Fake Bad Block History (S300)

When the selected memory block is determined as pass based on a result of the above-described status check operation (S290), the controller 200 does not determine the selected memory block as a real bad block but determines the selected memory block as a fake bad block.

The controller 200 may update fake or bad block history information by storing, in the system memory block (e.g., BLKz), information denoting the selected memory block as a fake bad block.

11) Re-Performance of Erase/Program Operation (S310)

After the above-described update of the fake bad block history (S300), the controller 200 may determine that the selected memory block is not a real bad block. Thus, the controller 200 may output, to the control logic 140, the command for the erase or program operation on the selected memory block. The control logic 140 may determine the selected memory block as a normal memory block, and continuously perform the erase or program operation.

As described above, in an operating method of the memory system according to embodiments of the present disclosure, when a selected memory block is determined as fail based on a result of the status check operation during the erase or program operation, the controller 200 may determine whether the selected memory block is a real bad block or a fake bad block by performing a verify operation. The verify operation may include the identification of the number of fake and/or bad block determination times (S230), the comparison of the in number of fail bits with the number of ECC maximum correctable bits (S250), and the status check operation (S290) after the re-performance of the erase/program operation (S280). Thus, the efficiency of the memory system may be further improved.

Moreover, in an embodiment, when the number of fail bits in a selected page of a selected memory block approaches the number of ECC maximum correctable bits, the controller 200 may perform a refresh operation including programming data stored in the selected page to another page of the same selected memory block or of another memory block, thereby improving the reliability of data.

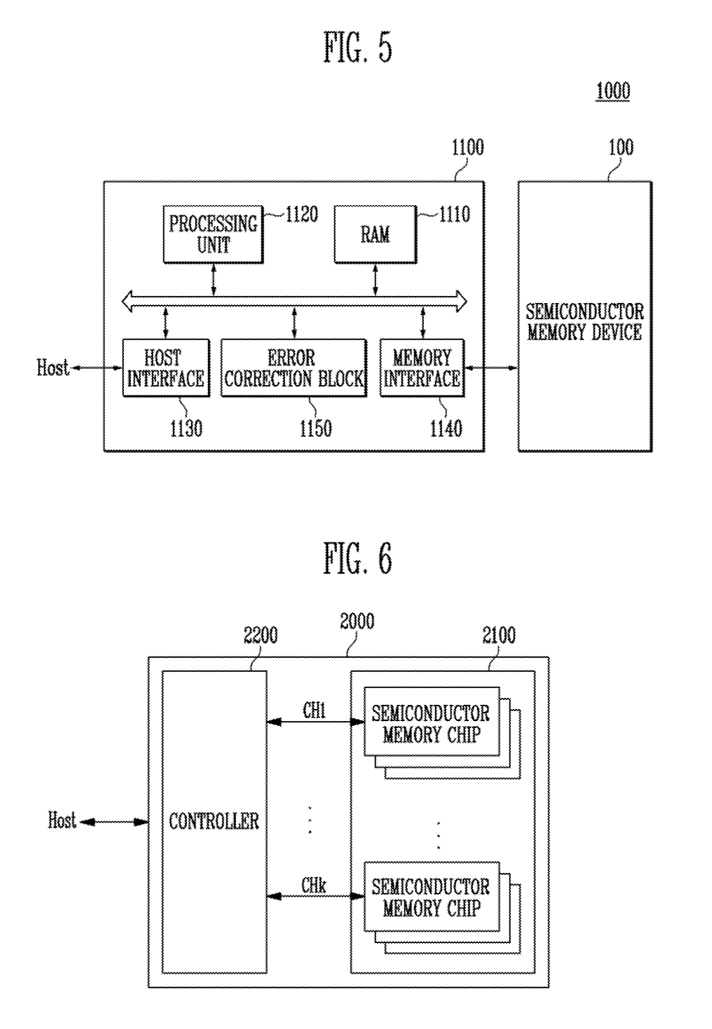

FIG. 5 is a block diagram of a memory system, according to another embodiment of the present disclosure.

Referring to FIG. 5, the memory system 1000 may include a semiconductor memory device 100 and a controller 1100.

The semiconductor memory device 100 may be configured and operated identically to the memory device 100 described with reference to FIG. 1. Hence, hereinafter, overlapping descriptions will be omitted

The controller 1100 may include functions identical to the functions of the controller 200 described with reference to FIG. 1. The controller 1100 may be connected to a host Host and the semiconductor memory device 100. The controller 1100 may control the flow of control signals and data between the host Host and the semiconductor memory device 100. The controller 1100 may be configured to access the semiconductor memory device 100 in response to a request from the host Host. For example, the controller 1100 may be configured to control read, write, erase, and any background operations of the semiconductor memory device 100. The controller 1100 may be configured to provide an interface between the semiconductor memory device 100 and the host Host. The controller 1100 may be configured to drive firmware for controlling the semiconductor memory device 100.

The controller 1100 may include a random access memory (RAM) 1110, a processing unit 1120, a host interface 1130, a memory interface 1140, and an error correction block 1150. The RAM 1110 may be used as an operation memory of the processing unit 1120, a cache memory between the semiconductor memory device 100 and the host Host, and/or a buffer memory between the semiconductor memory device 100 and the host Host.

The processing unit 1120 may control overall operations of the controller 1100. The processing unit 1120 may control the semiconductor memory device 100 to determine whether a selected memory block among a plurality of memory blocks included in the semiconductor memory device 100 may be a fake bad block or a real bad block when the selected memory block is determined as fail based on a result of a status check operation during an erase or program operation. For example, the processing unit 1120 may read fake bad block history information stored on a system memory block of the semiconductor memory device 100, and identify whether the selected memory block has a history of a fake bad block in the read fake bad block history information. Also, the processing unit 1120 determines whether error correction may be possible by performing an error detection operation on the selected memory block by using the error correction block 1150. Also, the processing unit 1120 may control the semiconductor memory device 100 so that the status check operation may be re-performed by initializing a command for a general operation being performed and re-performing the general operation. Based on the above-described operations, the processing unit 1120 may determine whether the selected memory block is a fake bad block or a real bad block.

The host interface 1130 may include a protocol for exchanging data between the host. Host and the controller 1100. As an exemplary embodiment, the controller 1100 may be configured to communicate with the host. Host through one or more various interface protocols, such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a private protocol and the like.

The memory interface 1140 may interface with the semiconductor memory device 100. For example, the memory interface 1140 may include a NAND or a NOR flash interface.

The error correction block 1150 may perform the same function of the error correction block 210 of FIG. 1. The error correction block 1150 may be configured to detect and correct an error of data received from the semiconductor memory device 100 by using an error correction code (ECC). As an exemplary embodiment, the error correction block 1150 may be provided as a component of the controller 1100.

The controller 1100 and the semiconductor memory device 100 may be integrated into a single semiconductor device. For example, the controller 1100 and the semiconductor memory device 100 may be integrated into a single semiconductor device, to constitute a memory card, such as a PC card (personal computer memory card international association (PCMCIA)), a compact flash (CF) card, a smart media card (SM or SMC), a memory stick, a multimedia card (MMC, RS-MMC or MMCmicro), an SD card (SD, miniSD, microSD or SDHC), a universal flash storage (UFS) and the like.

The controller 1100 and the semiconductor memory device 100 may be integrated into a single semiconductor device to constitute a semiconductor drive (solid state drive (SSD)). The semiconductor drive SSD may include a storage device configured to store data in a semiconductor memory. If the memory system 1000 is used as the semiconductor drive SSD, the operating speed of the host Host connected to the memory system 1000 may be improved substantially.

As another example, the memory system 1000 may be provided as one of various components of an electronic device, such as a computer, a ultra mobile PC (UMPC), a workstation, a net-book, a personal digital assistant (PDA), a portable computer, a web tablet, a wireless phone, a mobile phone, a smart phone, an e-book, a portable multimedia player (PMP), a portable game console, a navigation system, a black box, a digital camera, a 3-dimensional television, a digital audio recorder, a digital audio player, a digital picture recorder, a digital picture player, a digital video recorder, a digital video player, a device capable of transmitting/receiving information in a wireless environment, an electronic device for a home, computer, or telematics network, a radio frequency identification (RFID) device, one of various components that constitute a computing system and the like.

As an exemplary embodiment, the semiconductor memory device 100 or the memory system 1000 may be packaged in various forms. For example, the semiconductor memory device 100 or the memory system 1000 may be packaged in a manner such as package on package (PoP), ball grid array (BGA), chip scale package (CSP), plastic leaded chip carrier (PLCC), plastic dual in-line package (PDIP), die in Waffle pack, die in wafer form, chip on board (COB), ceramic dual in-line package (CERDIP), plastic metric quad flat pack (MQFP), thin quad flat pack (TQFP), small outline integrated circuit (SOIC), shrink small out line package (SSOP), thin small outline package (TSOP), system in package (SIP), multi chip package (MCP), wafer-level fabricated package (WFP), wafer-level processed stack package (WSP) and the like.

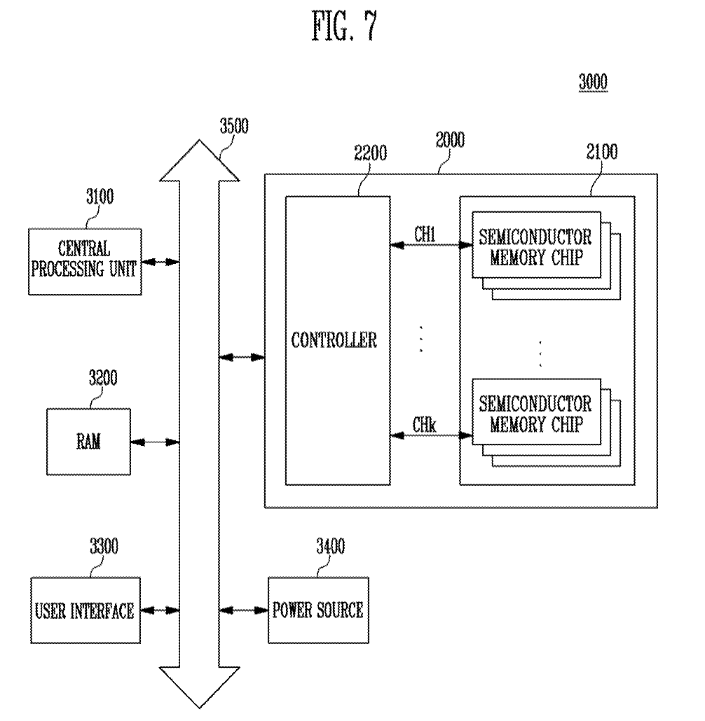

FIG. 6 is a block diagram illustrating an application example of the memory system of FIG. 5.

Referring to FIG. 6 the memory system 2000 may include a semiconductor memory device 2100 and a controller 2200. The semiconductor memory device 2100 may include a plurality of semiconductor memory chips. The plurality semiconductor memory chips may be divided into a plurality of groups. Each of the plurality of semiconductor memory chips may include a plurality of memory blocks. Each of the plurality of memory chips included in the semiconductor memory device 2100 may include a system memory block for storing bad block history information and fake bad block history information. In an embodiment, a system memory block may be included in only one memory chip among the plurality of memory chips. For example, when each of the plurality of memory chips may include a system memory block, the system memory block of each memory chip may store bad block information and fake bad block history information on the corresponding memory chip. When a system memory block is included in only one memory chip among the plurality of memory chips, the system memory block may store bad block information and fake bad block history information on the plurality of memory chips.

In FIG. 6, it is illustrated that the respective groups of the semiconductor memory chips communicate with the controller 2200 through first to kth channels CH1 to CHk. Each semiconductor memory chip may be configured and operated like the semiconductor memory device 100 described with reference to FIG. 1. Each group may be configured to communicate with the controller 2200 through one common channel. The controller 2200 may be configured similarly to the controller 1100 described with reference to FIG. 5. The controller 2200 may be configured to control the plurality of semiconductor memory chips of the semiconductor memory device 2100 through the plurality of channels CH1 to CHk.

FIG. 7 is a block diagram illustrating a computing system including the memory system described with reference to FIG. 6 according to an embodiment of the present disclosure.

Referring to FIG. 7, the computing system 3000 may include a central processing unit 3100, a RAM 3200, a user interface 3300, a power source 3400, a system bus 3500, and a memory system 2000.

The memory system 2000 may be electrically connected to the central processing unit 3100, the RAM 3200, the user interface 3300, and the power source 3400 through the system bus 3500. Data supplied through user interface 3300 or data processed by the central processing unit 3100 may be stored in the memory system 2000.

In FIG. 7, it is illustrated that the semiconductor memory device 2100 may be, connected, to the system bus 3500 through the controller 2200. However, the semiconductor memory device 2100 may be directly connected to the system bus 3500. In this case, the function of the controller 2200 may be performed by the central processing unit 3100 and the RAM 3200.

In FIG. 7, it is illustrated that the computing system 3000 may include the memory system 2000 described with reference to FIG. 6. However, the memory system 2000 may be replaced by the memory system 1000 described with reference to FIG. 5. As an exemplary embodiment, the computing system 3000 may include both the memory systems 1000 and 2000 described with reference to FIGS. 5 and 6.

According to embodiments of the present disclosure, when a memory block is determined as fail in a status check operation of the memory block, during a general operation of the memory system a determination of whether or not the memory block is a fake bad block or a real bad block may be made through a verify operation on the memory block, thereby improving the efficiency of the memory system.

Example embodiments have been disclosed herein, and although specific terms are employed, they are used and are to be interpreted in a generic and descriptive sense only and not for purpose of limitation. In some instances, as would be apparent to one of ordinary skill in the relevant art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the relevant art that various changes in form and details may be made without departing from the spirit and/or scope of the present disclosure as set forth in the following claims.

What is claimed is:

1. A memory system comprising:
a semiconductor memory device including a plurality of memory blocks; and
a controller suitable for controlling the semiconductor memory device to perform a first operation on a memory block selected among the plurality of memory blocks, the first operation including performing a status check for determining whether the selected memory block is a fail or a pass;
wherein if the selected memory block is determined as a fail the controller performs a second operation for determining whether the selected memory block is a fake bad block or a real bad block.

2. The memory system of claim wherein the first operation is a program operation and the second operation is a verify operation.

3. The memory system of claim 1, wherein the first operation is an erase operation and the second operation is a verify operation.

4. The memory system of claim 1, wherein at least one memory block among the plurality of memory blocks is a system memory block for storing bad block information and/or fake bad block history information.

5. The memory system of claim 4, wherein, when the controller performs the verify operation to identify a history of the selected memory block being determined as the fake bad block from the fake bad block history information stored in the system memory block, the controller determines the selected memory block as the real bad block.

6. The memory system of claim wherein the controller further includes:
an error correction block suitable for detecting and correcting fail bits of the selected memory block.

7. The memory system of claim 6, wherein, when the controller in the verify operation finds no history of the selected memory block in the fake bad block history information, and a number of fail bits of the selected memory block is greater than a number of error correction code (ECC) maximum correctable bits, the controller determines the selected memory block as the real bad block.

8. The memory system of claim 7, wherein, when the number of fail bits of the selected memory block is smaller than the number of ECC maximum correctable bits, the controller initializes a command for the program or erase operation and controls the semiconductor memory device to re-perform the program or erase operation and the status check operation, and
wherein, when the selected memory block is determined as fail based on a result of the re-performance of the status check operation, the controller determines the selected memory block as the real bad block.

9. The memory system of claim 5, wherein, when the selected memory block is determined as the fake bad block based on a result of the verify operation, the controller updates the fake bad block history information stored in the system memory block.

10. The memory system of claim 5, wherein, when the selected memory block is determined as the real bad block based on a result of the verify operation, the controller updates the bad block information stored in the system memory block.

11. The memory system of claim 5, wherein, when the controller performs the verify operation to identify, from the fake bad block history information stored in the system memory block, that the selected memory block is determined as a fake bad block more than a set number of times, the controller determines the selected memory block as the real bad block.

12. The memory system of claim 7, wherein, when the number of fail bits of the selected memory block is equal to or smaller than the number of ECC maximum correctable bits and greater than a number of ECC setting bits, the controller controls the semiconductor memory device to perform a refresh operation on the selected memory block.

13. The memory system of claim 12, wherein the refresh operation includes correcting errors of data stored in a selected page of the selected memory block and programming the data to another page of the selected memory block or another memory block of the plurality of memory blocks.

14. A method of operating a memory system, the method comprising:
performing a first operation of a selected memory block among a plurality of memory blocks said first operation including performing a status check operation on the selected memory block;
performing a second operation of determining whether the selected memory block is a real bad block or a fake bad block, when the selected memory block is determined as a fail based on a result of the status check operation; and
continuously performing the first operation on the selected memory block, when the selected memory block is determined as the fake bad block based on a result of the second operation.

15. The method of claim 14, wherein the first operation is a program or an erase operation and the second operation is a verify operation.

16. The method of claim 14, wherein at least one of the plurality of memory blocks are a system memory block for storing bad block information, fake bad block history information.

17. The method of claim 16, wherein the performing of the verify operation includes:
determining the selected memory block as the real bad block when the selected memory block has a history of being determined as the fake bad block in the fake bad block history information.

18. The method of claim 15, wherein the performing of the verify operation includes, when the selected memory block has no history in the fake bad block history information:
determining the selected memory block as the real bad block when a number of fail bits of the selected memory block is greater than a number of error correction code (ECC) maximum correctable bits, correctable by an error correction block.

19. The method of claim 15, wherein the performing of the verify operation further includes, when the selected memory block has no history in the fake bad block history information:
initializing a command of the program or erase operation and then re-performing the program or erase operation and the status check operation, when the number of fail bits of the selected memory block is smaller than the number of ECC maximum correctable bits,
wherein the selected memory block is determined as the real bad block when the selected memory block is determined as fail based on a result of the re-performance of the status check operation.

20. The method of claim 1, further comprising:
updating the fake bad block history information stored in the system memory block, when the selected memory block is determined as the fake bad block based on a result of the second operation.

21. A method of operating a memory system, the method comprising:
performing a program or erase operation of a selected memory block among a plurality of memory blocks;
performing a status check operation on the selected memory block; and
performing a first verify operation of determining whether the selected memory block is determined as a fake, bad block more than a set number of times when the selected memory block is determined as fail based on a result of the status check operation.

22. The method of claim 21, wherein the performing of the first verify operation may include:
comparing a number of times that the selected memory block is determined as a fake bad block with the set number of times, based on fake bad block history information stored in a system memory block among the plurality of memory blocks;and
determining the selected memory block as a rad bad block when the number of determination times is greater than the set number of times.

23. The method of claim 21 further comprising, when the selected memory block is determined as the fake bad block equal to or smaller than the set number of times as a result of the first verify operation;
performing a second verify operation of determining whether a number of fail bits of the selected memory block is greater than a number of error correction code (ECC) maximum correctable bits, correctable by an error correction block, or a number of ECC setting bits.

24. The method of claim 23, further comprising;
determining the selected memory block as the real bad block when the number of fail bits of the selected memory block is greater than the number of ECC maximum correctable bits as a result of the second verify operation; and
performing a refresh operation on the selected memory block, when the number of fail bits of the selected memory block is smaller than the number of ECC maximum correctable bits and greater than the number of ECC setting bits as the result of the second verify operation.

25. The method of claim 24, further comprising:
performing a third verify operation, when the number of fail bits of the selected memory block is equal to or smaller than the number of ECC setting bits as the result of the second verify operation,
wherein the third verify operation includes:
initializing a command for the program or erase operation;
re-performing the perform and erase operation and the status check operation; and
determining the selected memory block as the real bad block when the selected memory block is determined fail based on a result of the re-performance of the status check operation.
